(19) United States
(12) Patent Application Publication
(10) Pub. No.: US 2024/0373702 A1
(43) Pub. Date: Nov. 7, 2024

(54) DISPLAY PANEL AND MANUFACTURING METHOD THEREFOR, AND DISPLAY APPARATUS

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Yingbin HU, Beijing (CN); Ca ZHAO, Beijing (CN); Ming WANG, Beijing (CN); Shun WANG, Beijing (CN); Jiawen SONG, Beijing (CN); Yang XIA, Beijing (CN); Dongdong ZHANG, Beijing (CN); Yang ZHANG, Beijing (CN); Liangchen YAN, Beijing (CN); Ning LIU, Beijing (CN)

(21) Appl. No.: 18/689,267

(22) PCT Filed: Jun. 2, 2022
(86) PCT No.: PCT/CN2022/096901

§ 371 Date: Mar. 5, 2024

(51) Int. Cl. H10K 59/131; H10K 59/12; H10K 59/126; H10K 59/80; H10K 71/60

(52) U.S. Cl. CPC H10K 59/131; H10K 59/1201; H10K 59/126; H10K 59/80522; H10K 71/60

(57) ABSTRACT

A display panel and a method for manufacturing a display panel, and a display apparatus are provided. The display panel includes a substrate, a driving layer and a light-emitting layer, the driving layer includes a plurality of groups of pixel circuits, the source-drain metal layer of the driving layer includes an auxiliary electrode located on a side of a group of pixel circuits; the light-emitting layer includes a light-emitting device and a transition structure, a second electrode of the light emitting device covers at least a part of the transition structure and is connected to the auxiliary electrode.

### CROSS-REFERENCE TO RELATED APPLICATIONS

The present disclosure is a U.S. National Stage of International Application No. PCT/CN2022/096901, filed on Jun. 2, 2022, entitled “DISPLAY PANEL AND MANUFACTURING METHOD THEREFOR, AND DISPLAY APPARATUS”, the entire content of which is incorporated herein by reference.

### TECHNICAL FIELD

The present disclosure relates to a field of display technology, and more particularly, to a display panel and a method for manufacturing a display panel, and a display apparatus.

### SUMMARY

With rapid development of display panels, users have higher and higher requirements for the screen display of the screen panels. The display panel includes a plurality of light-emitting devices to achieve the screen display through light emission of the light-emitting devices. Each light-emitting device includes a first electrode, a light-emitting functional layer, and a second electrode that are sequentially stacked, and the plurality of light-emitting devices share the second electrode. In the process of controlling the screen display, due to influence of a voltage drop of the second electrode, potentials of the second electrode are uneven, such that luminous brightness of the plurality of light-emitting devices is different, resulting in uneven brightness of display screen.

It should be noted that the information disclosed in this section is turned only for enhancing understanding of the BACKGROUND of the disclosure and therefore, may contain information that does not constitute the prior art that is already known to those skilled in the art.

### SUMMARY

The present disclosure aims to provide a display panel, a method for manufacturing a display panel and a display apparatus.

According to a first aspect of the present disclosure, a display panel is provided and includes

a substrate;

a driving layer, located on a side of the substrate and including a plurality of groups of pixel circuits distributed along a row direction, where the driving layer includes a source-drain metal layer, the source-drain metal layer includes an auxiliary electrode in one-to-one correspondence with at least one group of pixel circuits, and the auxiliary electrode is located on a side of a group of pixel circuits corresponding to the auxiliary electrode; and

a light-emitting layer, located on a side of the driving layer away from the substrate, where the light-emitting layer includes a light-emitting device and a transition structure distributed at intervals, an orthographic projection of the transition structure on the substrate and an orthographic projection of the auxiliary electrode on the substrate have an overlapping region, the light-emitting device includes a first electrode, a light-emitting functional layer, and a second electrode sequentially distributed along a direction away from the substrate, the first electrode of the light-emitting device is connected to the pixel circuit, the light-emitting functional layer covers the first electrode and the transition structure, and forms a fracture on at least a partial edge of the transition structure, the second electrode covers the light-emitting functional layer and an exposed part of the transition structure at the fracture of the light-emitting functional layer, and the second electrode is connected to the auxiliary electrode.

For any display panel according to the present disclosure, the driving layer is defined with an aperture facing towards the light-emitting layer, and an orthographic projection of at least a partial edge of the transition structure on the substrate is located within an orthographic projection of the aperture on the substrate;

the auxiliary electrode includes an exposed portion at the aperture, the light-emitting functional layer includes a covering portion and a partition portion, where the covering portion and the partition portion form a fracture on at least a partial edge of the transition structure, the covering portion covers the first electrode and the transition structure, the partition portion is located within the aperture, and at least a partial edge of an orthographic projection of the exposed portion of the auxiliary electrode on the substrate extends beyond an orthographic projection of the partition portion on the substrate;

the second electrode covers a side of the transition structure, and a part of the exposed portion not covered by the partition portion, and a part of the second electrode covering the light-emitting functional layer and a part of the second electrode covering the exposed portion are continuous.

For any display panel according to the present disclosure, the transition structure is defined with an opening, and an orthographic projection of at least a partial opening edge of the transition structure on the substrate is located within the orthographic projection of the aperture on the substrate.

For any display panel according to the present disclosure, the opening of the transition structure coincides with a centerline of the aperture of the driving layer, and an opening size of the opening is less than an aperture size of the aperture.

For any display panel according to the present disclosure, a length of an edge of the transition structure extending into a corresponding region of the aperture is greater than or equal to 0.8 microns and less than or equal to 1.2 microns.

For any display panel according to the present disclosure, the transition structure includes a first conductive layer, a metal layer, and a second conductive layer distributed sequentially along the direction away from the substrate;

an orthographic projection of at least a partial edge of at least one structural layer in the first conductive layer, the metal layer, and the second conductive layer on the substrate is located within the orthographic projection of the aperture on the substrate, and there is no overlapping region between an orthographic projection of remaining structural layers on the substrate and the orthographic projection of the aperture on the substrate.

For any display panel according to the present disclosure, each of the first conductive layer, the metal layer, and the second conductive layer is defined with an opening;

an opening edge of the first conductive layer and an opening edge of the metal layer are flush with an aperture wall of the aperture, and an orthographic projection of at least a partial opening edge of the second conductive layer on the substrate is located within the orthographic projection of the aperture on the substrate.

For any display panel according to the present disclosure, the transition structure is connected to the auxiliary electrode through a via hole.

For any display panel according to the present disclosure, the transition structure includes a first conductive layer, a third conductive layer, a metal layer, and a second conductive layer distributed sequentially along the direction away from the substrate;

the first conductive layer is connected to the auxiliary electrode through a via hole, and a material of the third conductive layer is an inorganic material, an orthographic projection of the metal layer on the substrate is located within an orthographic projection of the third conductive layer on the substrate, and at least a partial edge of the second conductive layer extends beyond an edge of the metal layer;

the light-emitting functional layer covers the first electrode, the second conductive layer, and the third conductive layer, and the light-emitting functional layer forms a fracture on an edge of the second conductive layer to expose at least a part of the third conductive layer and/or a side of the metal layer, and the second electrode layer further covers a part of the third conductive layer not covered by the light-emitting functional layer and/or the side of the metal layer.

For any display panel according to the present disclosure, an edge of the orthographic projection of the metal layer on the substrate is located within an orthographic projection of the second conductive layer on the substrate.

For any display panel according to the present disclosure, the source-drain metal layer includes a plurality of power lines in one-to-one correspondence with the plurality of groups of pixel circuits, the power line is connected to a group of pixel circuits corresponding to the power line, and the power line located on a side of the group of pixel circuits corresponding to the power line away from the auxiliary electrode.

For any display panel according to the present disclosure, the auxiliary electrode is provided with an extension portion on a side of the auxiliary electrode away from the power line corresponding to the auxiliary electrode, and there is an overlapping region between the orthographic projection of the transition structure on the substrate and an orthographic projection of the extension portion on the substrate, and the second electrode covers the transition structure and is connected to the extension portion.

For any display panel according to the present disclosure, the pixel circuit includes a first transistor, a second transistor, a third transistor, and a storage capacitor;

a control electrode of the first transistor is connected to a first electrode plate of the storage capacitor and a first electrode of the second transistor, the first electrode of the first transistor is configured to load a power signal, and a second electrode of the first transistor is connected to a second electrode plate of the storage capacitor and a first electrode of the third transistor, and is connected to the first electrode;

a control electrode of the second transistor is configured to load a first scanning signal, and a second electrode of the second transistor is configured to load a data signal; and

a control electrode of the third transistor is configured to load a second scanning signal, and a second electrode of the third transistor is configured to load a sensing signal.

For any display panel according to the present disclosure, the driving layer includes:

a shielding layer, located on a side of the substrate and including a shielding piece;

a semiconductor layer, located on a side of the shielding layer away from the substrate, and including an active portion of the first transistor, an active portion of the second transistor, and an active portion of the third transistor, where the active portion includes a channel region and two connection portions located on both sides of the channel region;

a gate metal layer, located on a side of the semiconductor layer away from the substrate, and including a first scanning line, a second scanning line, and a second electrode plate of the storage capacitor, where the first scanning line loads the first scanning signal at the control electrode of the second transistor, and the second scanning line loads the second scanning signal at the control electrode of the third transistor;

a source-drain metal layer, located on a side of the gate metal layer away from the substrate, and including a power line, a data line, a sensing line, and a first electrode plate of the storage capacitor, where the power line loads the power signal at the first electrode of the first transistor, the data line loads the data signal at the second electrode of the second transistor, the sensing line loads the sensing signal at the second electrode of the third transistor, and the first electrode plate of the storage capacitor is directly opposite to the shielding piece and connected to the shielding piece through a via hole; and

a planarization layer, located on a side of the source-drain metal layer away from the substrate, and at least covers the power line, the data line, the sensing line, the first electrode plate of the storage capacitor, and the auxiliary electrode.

For any display panel according to the present disclosure, one group of pixel circuits includes a plurality of circuit units distributed in a column direction, the unit circuit includes four pixel circuits distributed in two rows and two columns, where for the circuit unit:

each the power line and the auxiliary electrode extends along the column direction and is distributed along the row direction, the power line loads the power signal at the first electrodes of the first transistors of the four pixel circuits;

four shielding pieces are located between the power line and the auxiliary electrode, and orthographic projections of the first and second electrode plates of each storage capacitor on the substrate is located within an orthographic projection of the shielding piece of the same pixel circuit on the substrate;

each of the first scanning line and the second scanning line extends in the row direction and is located between two shielding pieces along the column direction, the first scanning line loads the first scanning signal at the control electrodes of the second transistors of the four pixel circuits, and the second scanning line loads the second scanning signal at the control electrodes of the third transistors of the four pixel circuits;

the data line extends along the column direction, and the data line is provided on both sides of the two shielding pieces along the row direction, and four data lines are located between the power line and the auxiliary electrode, and one data line loads the data signal at the second electrode of the second transistor of one pixel circuit; and

the sensing line extends along the column direction and is located between the two shielding pieces in the row direction, and the sensing line loads the sensing signal for the second electrodes of the third transistors of the four pixel circuits.

According to a second aspect of the present disclosure, a method for manufacturing a display panel is provided and includes:

providing a substrate;

manufacturing a driving layer on a side of the substrate, where the driving layer includes a plurality of groups of pixel circuits distributed along a row direction, the driving layer includes a source-drain metal layer, the source-drain metal layer includes an auxiliary electrode in one-to-one correspondence with at least one group of pixel circuits, and the auxiliary electrode is located on a side of a group of pixel circuits corresponding to the auxiliary electrode;

manufacturing a first electrode layer on a side of the driving layer away from the substrate, where the first electrode layer includes a first electrode and a transition structure distributed at intervals, the first electrode is connected to the pixel circuit, and an orthographic projection of the transition structure on the substrate and an orthographic projection of the auxiliary electrode on the substrate have an overlapping region;

etching the transition structure and the driving layer to form an aperture facing towards the first electrode layer and exposing the auxiliary electrode in the driving layer, where an orthographic projection of at least a partial edge of the transition structure on the substrate is located within an orthographic projection of the aperture on the substrate;

manufacturing a light-emitting functional layer on a side of the first electrode layer away from the substrate, where the light-emitting functional layer includes a covering portion and a partition portion, the covering portion covers the first electrode and the transition structure, the partition portion is located within the aperture, and the covering portion and the partition portion form a fracture on at least a partial edge of the transition structure, and at least a partial edge of an orthographic projection of the exposed portion of the auxiliary electrode on the substrate extends beyond an orthographic projection of the partition portion on the substrate;

manufacturing a second electrode layer on a side of the light-emitting functional layer away from the substrate, where the second electrode layer covers the light-emitting functional layer, and a part of the exposed portion of the auxiliary electrode not covered by the partition portion.

According to a third aspect of the present disclosure, a method for manufacturing a display panel is provided and includes:

providing a substrate;

manufacturing a driving layer on a side of the substrate, where the driving layer includes a plurality of groups of pixel circuits distributed along a row direction, the driving layer includes a source-drain metal layer, the source-drain metal layer includes an auxiliary electrode in one-to-one correspondence with at least one group of pixel circuits, and the auxiliary electrode is located on a side of a group of pixel circuits corresponding to the auxiliary electrode;

manufacturing a first electrode layer on a side of the driving layer away from the substrate, where the first electrode layer includes a first electrode and a transition structure distributed at intervals, the first electrode is connected to the pixel circuit, and the transition structure includes a first conductive layer, a third conductive layer, a metal layer, and a second conductive layer distributed sequentially along a direction away from the substrate, a material of the third conductive layer is an inorganic material, an orthographic projection of the metal layer on the substrate is located within an orthographic projection of the third conductive layer on the substrate, and at least a partial edge of the second conductive layer extends beyond an edge of the metal electrical layer;

manufacturing a light-emitting functional layer on a side of the first electrode layer away from the substrate, where the light-emitting functional layer covers the first electrode, the second conductive layer, and the third conductive layer, and the light-emitting functional layer forms a fracture on an edge of the second conductive layer to expose at least a part of the third conductive layer and/or a side of the metal layer;

manufacturing a second electrode layer on a side of the light-emitting functional layer away from the substrate, where the second electrode layer covers the light-emitting functional layer, and a part of the third conductive layer not covered by the light-emitting functional layer and/or a side of the metal layer.

According to a fourth aspect of the present disclosure, a display apparatus is provided and includes the display panel according to the above first aspect.

It should be understood that the preceding general description and the following detailed description are exemplary and explanatory only and are not restrictive of the present disclosure.

### BRIEF DESCRIPTION OF THE DRAWINGS

The accompanying drawings here are incorporated in the specification and constitute a part of this specification, show embodiments in accordance with the present disclosure and serve to explain the principles of the present disclosure together with the specification. Obviously, the drawings in the following description are turned only some embodiments of the present disclosure, and for those ordinary skills in the art, other drawings may also be obtained from these drawings without creative efforts.

FIG. 1 is a schematic diagram of a cross-sectional structure of a display panel provided in an embodiment of the present disclosure.

FIG. 2 is a schematic diagram of a cross-sectional structure of another display panel provided in an embodiment of the present disclosure.

FIG. 3 is a schematic diagram of a layout of a driving layer provided in an embodiment of the present disclosure.

FIG. 4 is a schematic diagram of a layout of a source-drain metal layer provided in an embodiment of the present disclosure.

FIG. 5 is a schematic diagram of a layout of another driving layer provided in an embodiment of the present disclosure.

FIG. 6 is a schematic diagram of a pixel circuit provided in an embodiment of the present disclosure.

FIG. 7 is a schematic diagram of a layout of a shielding layer provided in an embodiment of the present disclosure.

FIG. 8 is a schematic diagram of a layout of a semiconductor layer provided in an embodiment of the present disclosure.

FIG. 9 is a schematic diagram of a layout of a gate metal layer provided in an embodiment of the present disclosure.

FIG. 10 is a flowchart of a method for manufacturing a display panel provided in an embodiment of the present disclosure.

FIG. 11 is a flowchart of another method for manufacturing a display panel provided in an embodiment of the present disclosure.

### DETAILED DESCRIPTION

Example embodiments will now be described more fully with reference to the accompanying drawings. However, the embodiments may be implemented in a variety of forms and should not be construed as being limited to the examples set forth herein. Rather, these embodiments are provided such that the present disclosure will be more complete so as to convey the idea of the exemplary embodiments to those skilled in this art. The same reference numerals in the drawings denote the same or similar parts, and the repeated description thereof will be omitted. In addition, the drawings are merely schematic representations of the present disclosure and are not necessarily drawn to scale.

Although relative terms such as “upper” and “lower” are used in this specification to describe the relative relationship of one component shown to another component, these terms are used in this specification only for convenience of description for example according to the direction of the example described. It may be understood that if a device shown is turned upside down, a component described as being “upper” will become a “lower” component. When a certain structure is “on” another structure, it may mean that the certain structure is integrally formed on said another structure, or that the certain structure is “directly” arranged on said another structure, or that the certain structure is “indirectly” arranged on said another structure through an additional structure.

The terms “a”, “an”, “the”, “said” and “at least one” are used to indicate the presence of one or more elements/components/etc.; the terms “include” and “have” are used to indicate an open type meaning of including and means that there may be additional elements/components/etc. in addition to the listed elements/components/etc.; and the terms “first”, “second” and “third” are used as labels only, not a limitation on the number of objects.

A transistor refers to an element at least including three terminals, namely a gate electrode, a drain electrode and a source electrode. A transistor has a channel region between a drain electrode (drain electrode terminal, drain region or drain electrode) and a source electrode (source electrode terminal, source region or source electrode), and current may flow through the drain electrode, the channel region and the source electrode. A channel region refers to a region through which current mainly flows.

A first electrode may be a drain electrode and a second electrode may be a source electrode, or the first electrode may be a source electrode and the second electrode may be a drain electrode. Functions of the “source electrode” and the “drain electrode” are sometimes interchanged, in a case that transistors with opposite polarities are used, or in a case that a current direction changes during circuit operation, or the like. Thus, in the present disclosure, the “source electrode” and the “drain electrode” may be interchanged.

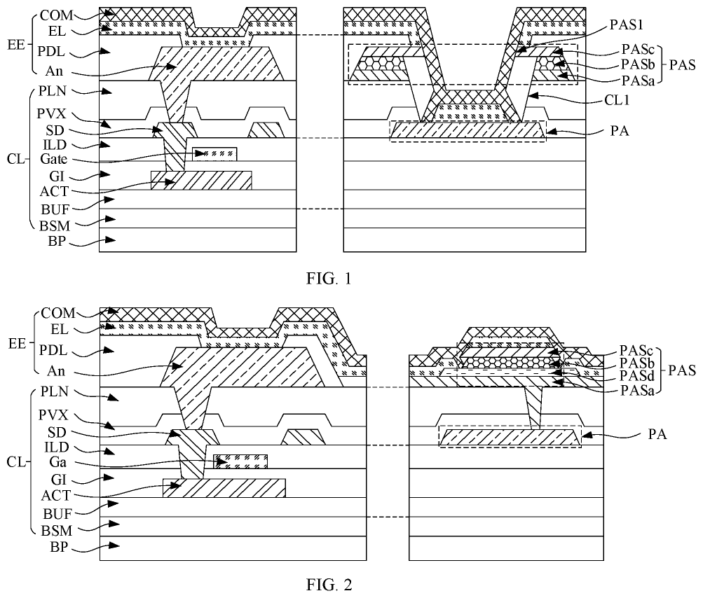

Embodiments of the present disclosure provide a display panel, as shown in FIG. 1 or FIG. 2, the display panel includes a substrate BP, a driving layer CL, and a light-emitting layer EE. The driving layer CL is located on a side of the substrate BP, and the light-emitting layer EE is located on a side of the driving layer CL away from the substrate BP. The driving layer CL includes a plurality of pixel circuits PDCAs, the light-emitting layer EE includes a plurality of light-emitting devices distributed in an array, the plurality of pixel circuits PDCAs are in one-to-one correspondence with the plurality of light-emitting devices, and the light-emitting device is connected to a corresponding pixel circuit PDCA, such that the corresponding light-emitting device may be controlled to emit light under the driving of the pixel circuit PDCA, to achieve the screen display on the display panel.

A material of the substrate BP may be an inorganic or an organic material. For example, in some embodiments, the material of the substrate BP may be glass material such as soda-lime glass, quartz glass, sapphire glass, etc., or may be metallic material such as stainless steel, aluminum, nickel, etc. In some embodiments, the material of the substrate BP may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), Polyethylene naphthalate (PEN), or a combination thereof.

Optionally, the substrate BP may not only be a single-layered material, but also a composite of multi-layered materials. For example, in some embodiments, the substrate BP may include a bottom film layer, a pressure-sensitive adhesive layer, a first polyimide layer and a second polyimide layer sequentially stacked.

In the embodiments of the present disclosure, one pixel circuit PDCA may include a plurality of transistors and a storage capacitor CP.

The transistor may be a thin film transistor, and the thin film transistor may be selected from a top gate thin film transistor, a bottom gate thin film transistor or a double gate thin film transistor; and the storage capacitor may be a duplicated-plate capacitor or a triplicated-plate capacitor. A material of an active layer of the thin film transistor may be an amorphous silicon semiconductor material, a low-temperature polycrystalline silicon semiconductor material, a metal oxide semiconductor material, an organic semiconductor material, or another type of semiconductor material; and the thin film transistor may be an N-type thin film transistor or a P-type thin film transistor.

It may be understood that in the plurality of transistors included in one pixel circuit PDCA, types of any two transistors may be the same or different. For example, in some embodiments, some transistors in one pixel circuit PDCA may be the N-type transistors and some transistors may be the P-type transistors. For example, in some other embodiments, the material of active layers of some transistors in one pixel circuit PDCA may be the low-temperature polycrystalline silicon semiconductor material, and the material of the active layers of some transistors may be the metal oxide semiconductor material.

In the embodiments of the present disclosure, as shown in FIG. 1 or 2, the driving layer CL includes an insulation buffer layer BUF, a transistor layer, an interlayer dielectric layer ILD, a source-drain metal layer SD, and a planarization layer PLA sequentially distributed in a direction away from the substrate BP. The transistor layer includes a semiconductor layer ACT, a gate insulation layer GI, and a gate metal layer Ga stacked between the substrate BP and the interlayer dielectric layer ILD. A position relationship of each film layer included in the transistor layer may be determined according to film layer structures of the thin film transistor.

In some embodiments, a material of the insulation buffer layer BUF may be an inorganic insulation material such as silicon oxide and silicon nitride, and the insulation buffer layer BUF may be a single-layered inorganic material or a multi-layered inorganic material. The semiconductor layer ACT may be configured to form an active portion of each transistor included in the pixel circuit PDCA. Each active part includes a channel region and two connection portions (i.e., a source and a drain) located on both sides of the channel region. The channel region may maintain semiconductor characteristics, and the semiconductor material corresponding to the two connection portions are partially or fully conductive. The gate metal layer Ga may be configured to form a gate metal layer wiring such as a scanning line, and may also be configured to form the second electrode plate CP2 of the storage capacitor CP. The source-drain metal layer SD may be configured to form a source-drain metal layer wiring, such as a power line VDD, a data line DA, a sensing line SE, and a connection line, etc, and may also be configured to form the first electrode plate CP1 of the storage capacitor CP. The planarization layer PLN is defined with a plurality of first via holes, the plurality of pixel circuits PDCAs, the plurality of first via holes, and the plurality of light-emitting devices are in one-to-one correspondence, and a first electrode An of a light-emitting device is connected to a corresponding pixel circuit PDCA through the a corresponding first via hole.

In some embodiments, as shown in FIG. 1 or FIG. 2, the transistor layer includes a semiconductor layer ACT, a gate insulation layer GI, and a gate metal layer Ga sequentially stacked in a direction away from the substrate BP, and the resulting thin film transistor is a top gate thin film transistor. In some other embodiments, the transistor layer includes a gate metal layer Ga, a gate insulation layer GI, and a semiconductor layer ACT sequentially stacked in a direction away from the substrate BP, and the resulting thin film transistor is a bottom gate thin film transistor.

In some embodiments, the semiconductor layer ACT may be a single-layered semiconductor layer ACT or a two-layer semiconductor layer ACT. For example, the semiconductor layer ACT includes a low-temperature polycrystalline silicon semiconductor layer ACT. The gate metal layer Ga may be a single-layered gate metal layer Ga, or a two-layer or three-layer gate metal layer Ga. For example, the gate metal layer Ga includes a single-layered gate metal layer Ga.

It may be understood that when the gate metal layer Ga or the semiconductor layer ACT has a multi-layered structure, the gate insulation layer GI in the transistor layer may be adaptively increased or decreased. For example, in some embodiments, the transistor layer included in the driving layer CL includes a low-temperature polycrystalline silicon semiconductor layer, a gate insulation layer GI, and a single-layered gate metal layer Ga sequentially stacked on the substrate BP.

In some embodiments, the source-drain metal layer SD may be a single-layered source-drain metal layer SD, or a two-layer or three-layer source-drain metal layer SD. For example, the source-drain metal layer SD included in the driving layer CL includes a single-layered source-drain metal layer SD.

Optionally, as shown in FIG. 1 or FIG. 2, the driving layer CL also includes a passivation layer PVX provided between the source-drain metal layer SD and the planarization layer PLA, to achieve protection of the source-drain metal layer SD through the arrangement of the passivation layer PVX.

Optionally, as shown in FIG. 1 or FIG. 2, the driving layer CL also includes a shielding layer BSM located between the insulation buffer layer BUF and the substrate BP. The shielding layer BSM may overlap with at least part of the channel region of the transistor to block light irradiating toward the transistor, thereby stabilizing the electrical characteristics of the transistor.

In the embodiments of the present disclosure, the light-emitting device may be an organic electroluminescent diode, a micro-luminescent diode, a quantum dot-organic electroluminescent diode, a quantum dot light-emitting diode or another type of light-emitting device.

For example, in some embodiments, the light-emitting device is the organic electroluminescent diode, the display panel is an OLED display panel. As follows, taking the light-emitting device as an organic electroluminescent diode as an example, a feasible structure of the light-emitting device is introduced as an example.

Optionally, as shown in FIG. 1 or FIG. 2, the light-emitting layer EE further includes a pixel definition layer PDL located on a side of the driving layer CL away from the substrate BP, and the pixel definition layer PDL is provided with pixel openings in one-to-one correspondence with the plurality of light-emitting devices. The light-emitting device include a first electrode An, a light-emitting functional layer EL, and a second electrode COM sequentially distributed and stacked in a direction away from the substrate BP. The first electrode An is connected to a pixel circuit PDCA through a via hole. The first electrode An includes an exposed region exposed at a corresponding pixel opening and a region covered by the pixel definition layer PDL, and the exposed region of the first electrode An forms a light-emitting region of the corresponding light-emitting device.

In the embodiment, the light-emitting layer EL may include an organic electroluminescent material layer, and may include one or more of a hole injection layer, a hole transport layer, an electron blocking layer, a hole blocking layer, an electron transport layer and an electron injection layer.

In some embodiments, the display panel may further include a thin film encapsulation layer. The thin film encapsulation layer is provided on a side of the light-emitting layer EE away from the substrate BP, and may include alternately stacked inorganic encapsulation layer and organic encapsulation layer. The inorganic encapsulation layer may effectively block external moisture and oxygen, preventing water and oxygen from invading the organic light-emitting functional layer EL and causing material degradation. The organic encapsulation layer is located between two adjacent inorganic encapsulation layers to achieve planarization and reduce stress between the inorganic encapsulation layers.

The display panel is provided with a display region and a peripheral region located on the periphery of the display region. An edge of the inorganic encapsulation layer may be located in the peripheral region, and an edge of the organic encapsulation layer may be located between an edge of the display region and the edge of the inorganic encapsulation layer. Exemplarily, the thin film encapsulation layer includes a first inorganic encapsulation layer, an organic encapsulation layer and a second inorganic encapsulation layer sequentially stacked on the side of the light-emitting layer EE away from the substrate BP.

In some embodiments, the display panel may further include a touch functional layer, and the touch functional layer is provided on a side of the thin film encapsulation layer away from the substrate BP, and is used to implement a touch operation of the display panel.

In the embodiments of the present disclosure, as shown in FIG. 1 or FIG. 2, the light-emitting device includes a first electrode An, a light-emitting functional layer EL, and a second electrode COM distributed sequentially along a direction away from the substrate BP. For a top-emitting light-emitting device, taking the second electrode COM as a cathode an example, in order to ensure the luminous effect of the light-emitting device, the second electrode COM needs to be made of a material with high transmittance, low resistance, and low power function match.

In the related art, commonly used materials for the second electrode COM are IZO, Mg/Ag alloys, etc. Although these materials have good transmittance, the resistance of these materials is relatively great, which leads to a large voltage drop of the second electrode COM, and that is, potentials of the second electrodes COM of the plurality of light-emitting devices are uneven. In order to ensure that the second electrode COM has good transmittance and a relatively small voltage drop, an auxiliary electrode PA spaced apart from the first electrode An is usually manufactured at the same time as the first electrode An is manufactured, and the second electrode COM is connected to the auxiliary electrode PA. In this manner, an effective area of the second electrode COM is increased, so as to achieve a reduction in the voltage drop.

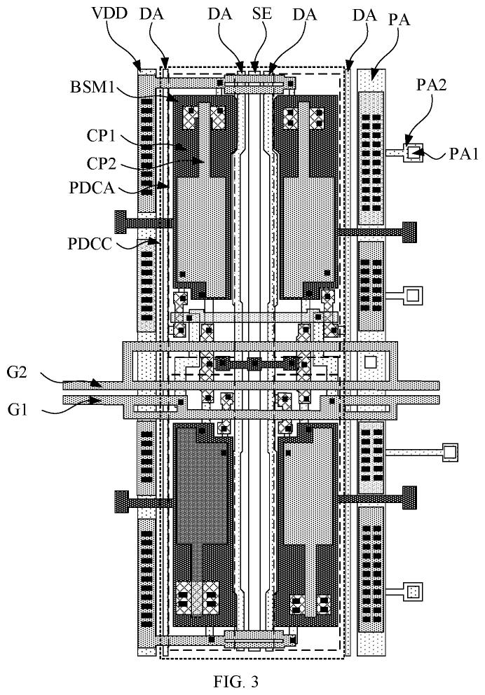

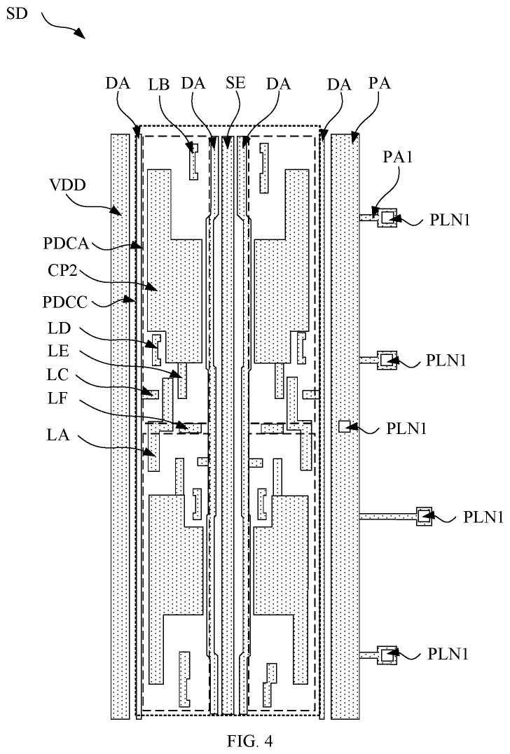

In the embodiments of the present disclosure, as shown in FIGS. 3 and 4, the driving layer CL includes a plurality of groups of pixel circuits PDCAs distributed along a row direction, the driving layer CL includes a source-drain metal layer SD, the source-drain metal layer SD includes an auxiliary electrodes PA in one-to-one correspondence with at least one group of pixel circuits PDCAs, and one auxiliary electrode PA is located on a side of the corresponding group of pixel circuits PDCAs. As shown in FIG. 1 or FIG. 2, the light-emitting layer EE includes a light-emitting device and a transition structure PAS distributed at intervals, an orthographic projection of the transition structure PAS on the substrate and an orthographic projection of the auxiliary electrode PA on the substrate BP have an overlapping region. The light-emitting functional layer EL of the light-emitting device covers both the first electrode An and the transition structure PAS, and a fracture is formed on at least at a partial edge of the transition structure PAS. The second electrode COM of the light-emitting device covers both the light-emitting functional layer EL, and an exposed part of the transition structure PAS at the fracture of the light-emitting functional layer EL, and is connected to the auxiliary electrode PA.

In this way, through the arrangement of the auxiliary electrode PA in the source-drain metal layer SD and the connection between the second electrode COM and the auxiliary electrode PA, the voltage drop of the second electrode COM may be effectively reduced, thereby effectively improving the potential uniformity of the second electrodes COM of the plurality of light-emitting devices, and ensuring the uniformity of brightness of the display panel when displaying an image. In addition, for the auxiliary electrode PA provided in the source-drain metal layer SD, the auxiliary electrode PA may be arranged to extend in a column direction, to effectively increase an area of the orthographic projection of the auxiliary electrode PA on the substrate BP, thereby further reducing the voltage drop of the second electrode COM. Furthermore, through the arrangement of the transition structure PAS, a problem of a fracture, occurring at the periphery of the light-emitting device, of the second electrode COM is avoided, and when the light-emitting device is subsequently encapsulated through the encapsulation layer, a problem of a fracture, occurring at the periphery of the light-emitting device, of the organic film layer included in the encapsulation layer is avoided. As for the manufacturing process, the light-emitting functional layer EL may cover both the first electrode An and the transition structure PAS, so as to simplify the manufacturing process compared to the patterned light-emitting functional layer EL.

For the plurality of groups of pixel circuits PDCAs, it may be that each group of pixel circuits PDCAs in a part of groups of pixel circuits PDCAs has a corresponding auxiliary electrode PA, or it may be that each group of pixel circuits PDCAs in the plurality of groups of pixel circuits PDCAs has a corresponding auxiliary electrode PA, which is not limited by the embodiments of the present disclosure.

In one embodiment, as shown in FIG. 1, the driving layer CL is defined with an aperture CL1 facing towards the light-emitting layer EE, and an orthographic projection of at least a partial edge of the transition structure PAS on the substrate BP is located within an orthographic projection of the aperture CL1 on the substrate BP; the auxiliary electrode PA includes an exposed portion PA1 at the aperture CL1, the light-emitting functional layer EL includes a covering portion and a partition portion, the covering portion and the partition portion form a fracture on at least at a partial edge of the transition structure PAS, the covering portion covers the first electrode An and the transition structure PAS, the partition portion is located within the aperture CL1, and at least a partial edge of an orthographic projection of the exposed portion PA1 of the auxiliary electrode PA on the substrate BP extends beyond an orthographic projection of the partition portion on the substrate BP; the second electrode COM covers a side of the transition structure PAS, and a part of the exposed portion PA1 that is not covered by the partition portion, and a part of the second electrode COM covering the light-emitting functional layer EL and a part of the second electrode covering the exposed portion PA1 are continuous.

In this way, the second electrode COM covers a part of the exposed portion PA1 of the auxiliary electrode PA, so as to achieve the connection between the second electrode COM and the auxiliary electrode PA. For the transition structure PAS, it is only necessary to ensure that the orthographic projection of at least a partial edge of the transition structure PAS on the substrate BP is located within the orthographic projection of the aperture CL on the substrate BP, thereby avoiding a case where a thickness of the transition structure PAS is relatively large and reducing a possibility of bulging during the manufacturing of the transition structure PAS. In addition, when the first electrodes An of the plurality of light-emitting devices are obtained by etching, the transition structures PAS may be obtained by etching simultaneously without manufacturing the transition structure PAS separately, so as to simplify the manufacturing process.

In the manufacturing process of the light-emitting layer EE, in a case where the driving layer CL is defined with the aperture CL1 and the orthographic projection of at least a partial edge of the transition structure PAS on the substrate BP is located within the orthographic projection of the aperture CL1 on the substrate BP, during the manufacturing of the light-emitting functional layer EL, the light-emitting functional layer EL may form a fracture on at least a partial edge of the transition structure PAS, and that is, there is the fracture between the above covering portion and the partition portion, so as to ensure that after the formation of the light-emitting functional layer EL, there is still a part of the exposed portion PA1 of the auxiliary electrode PA that is not covered by the light-emitting functional layer EL, such that when the second electrode COM is continuously manufactured, it may be ensured that the second electrode COM covers the part of the exposed portion PA1 of the auxiliary electrode PA that is not covered by the light-emitting functional layer EL, to achieve the connection between the second electrode COM and the auxiliary electrode PA.

An edge of the transition structure PAS at least includes a peripheral edge, which may be determined according to a shape of the transition structure PAS. For example, the transition structure PAS is defined with a notch or an opening PAS1, and the edge of the transition structure PAS includes a peripheral edge and a notch edge or an opening edge. For the peripheral edge of the transition structure PAS, only an orthographic projection of a part of the peripheral edge on the substrate BP is located within the orthographic projection of the aperture CL1 on the substrate BP; for the notch edge and the opening edge of the transition structure PAS, taking the opening edge as an example, it may be that an orthographic projection of a part of the opening edge of the transition structure PAS on the substrate BP is located within the orthographic projection of the aperture CL1 on the substrate BP, or an orthographic projection of the entire opening edge of the transition structure PAS on the substrate BP is located within the orthographic projection of the aperture CL1 on the substrate BP, as long as the planarization layer PLN is able to ensure the support of the transition structure PAS, and the embodiments of the present disclosure are not limited herein.

Taking the opening edge of the transition structure PAS as an example, when the orthographic projection of the entire opening edge of the transition structure PAS on the substrate BP is located within the orthographic projection of the aperture CL1 on the substrate BP, it may increase the probability of the fracture, occurring at the opening edge of the transition structure PAS, of the light-emitting functional layer EL, and ensure that the exposed portion PA1 of the auxiliary electrode PA is not completely covered by the light-emitting functional layer EL.

Taking the transition structure PAS being defined with an opening PAS1 as an example, as shown in FIG. 1, the opening PAS1 of the transition structure PAS coincides with a centerline of the aperture CL1 of the driving layer CL, and an opening PAS1 size of the opening PAS1 is less than an aperture CL1 size of the aperture CL1. That is, the orthographic projection of the entire open edge of the transition structure PAS on the substrate BP is located within the orthographic projection of the aperture CL1 on the substrate BP.

In combination with the above, the driving layer CL includes a planarization layer PLN located on a side of the source-drain metal layer SD away from the substrate BP, the planarization layer PLN is defined with an aperture CL1 to expose a part of the auxiliary electrode PA. The planarization layer PLA may be defined with one aperture CL1 for exposing the auxiliary electrode PA, or a plurality of apertures CL1 for exposing the auxiliary electrode PA, such that the second electrode COM is connected to the auxiliary electrode PA at a plurality of positions, so as to ensure the stability of the connection.

The aperture CL1 on the planarization layer PLN may be obtained and etched according to the position of the transition structure PAS after the transition structure PAS is formed, so as to ensure that the orthographic projection of at least a partial edge of the transition structure PAS on the substrate BP is located within the orthographic projection of the aperture CL1 on the substrate BP.

When the aperture CL1 is defined on the planarization layer PLN, in order to ensure that the light-emitting functional layer EL is able to form the fracture on at the edge of the transition structure PAS and the light-emitting functional layer EL cannot fully cover the exposed portion PA1 of the auxiliary electrode PA, a length of an edge of the transition structure PAS extending into a corresponding region of the aperture CL1 is greater than or equal to 0.8 microns and less than or equal to 1.2 microns. That is, a radial size of the overlapping region of the orthographic projections of the transition structure PAS and the aperture CL1 on the substrate BP is greater than or equal to 0.8 microns and less than or equal to 1.2 microns.

In the embodiments of the present disclosure, the transition structure PAS may be a single-layered structure or a multi-layered structure. When the transition structure PAS is the single-layered structure, the material of the transition structure PAS may be ITO or another conductive material; when the transition structure PAS is the multi-layered structure, for example, as shown in FIG. 1, the transition structure PAS includes a first conductive layer PASa, a metal layer PASb, and a second conductive layer PASc distributed sequentially along a direction away from the substrate BP.

An orthographic projection of at least a partial edge of at least one structural layer in the first conductive layer PASa, the metal layer PASb, and the second conductive layer PASc on the substrate BP is located within the orthographic projection of the aperture CL1 on the substrate BP, and there is no overlapping region between an orthographic projection of remaining structural layers BP on the substrate and the orthographic projection of the aperture CL on the substrate BP. In this way, during a subsequent manufacturing process of the light-emitting functional layer EL, it may be ensured that the light-emitting functional layer EL forms a fracture on at least the partial edge.

An edge of any structural layer may be a peripheral edge as described above, or a notch edge or an opening edge of the PAS transition structure as described above. For example, as shown in FIG. 1, the first conductive layer PASa, the metal layer PASb, and the second conductive layer PASc all have an opening PAS1, an opening edge of the first conductive layer PASa and an opening edge of the metal layer PASb are flush with an aperture wall of the aperture CL1, and an orthographic projection of at least a partial opening edge of the second conductive layer PASc on the substrate BP is located within the orthographic projection of the aperture CL1 on the substrate BP.

The material for the first conductive layer PASa and the second conductive layer PASc may both be ITO, etc., the material for the metal layer PASb may be Al, Al alloy, Ag, etc. A thickness of the metal layer PASb is greater than or equal to 30 nanometers and less than or equal to 150 nanometers, and a thickness of the second conductive layer PASc is greater than or equal to 10 nanometers and less than or equal to 140 nanometers.

In another embodiment, as shown in FIG. 2, the transition structure PAS is connected to the auxiliary electrode PA through a via hole. Thus, in a case where the second electrode COM covers at least a part of the transition structure PAS, the connection between the second electrode COM and the auxiliary electrode PA is achieved.

In this case, in order to ensure that the second electrode COM covers at least a part of the transition structure PAS, in some embodiments, the transition structure PAS includes a first conductive layer PASa, a metal layer PASb, and a second conductive layer PASc distributed sequentially along a direction away from the substrate BP; the first conductive layer PASa is connected to the auxiliary electrode PA through a via hole, an orthographic projection of the metal layer PASb on the substrate BP is located within an orthographic projection of the first conductive layer PASa on the substrate BP, and at least a partial edge of the second conductive layer PASc extends beyond an edge of the metal layer PASb. In this way, an I-shaped structure is formed through the first conductive layer PASa, the metal layer PASb, and the second conductive layer PASc.

The light-emitting functional layer EL covers the first electrode An, the second conductive layer PASc, and the first conductive layer PASa, and the light-emitting functional layer EL forms the fracture under the action of the I-shaped transition structure PAS, and that is, the light-emitting functional layer EL forms the fracture at the edge of the second conductive layer PASc, to expose at least a part of the first conductive layer PASa and/or a side of the metal layer. The second electrode COM not only covers the light-emitting functional layer EL, but also covers a part of the first conductive layer PASa that is not covered by the light-emitting functional layer EL and/or the side of the metal layer. In this way, it may be achieved that the second electrode COM covers at least a part of the transition structure PAS.

In some other embodiments, as shown in FIG. 2, the transition structure PAS includes a first conductive layer PASa, a third conductive layer PASd, a metal layer PASb, and a second conductive layer PASc distributed sequentially along the direction away from the substrate BP. The first conductive layer PASa is connected to the auxiliary electrode PA through a via hole, and a material of the third conductive layer PASd is an inorganic material, an orthographic projection of the metal layer PASb on the substrate BP is located within an orthographic projection of the third conductive layer PASd on the substrate BP, and at least a partial edge of the second conductive layer PASc extends beyond an edge of the metal layer PASb. In this way, an I-shaped structure is formed through the third conductive layer PASd, the metal layer PASb, and the second conductive layer PASc.

As shown in FIG. 2, the light-emitting functional layer EL covers the first electrode An, the second conductive layer PASc, and the third conductive layer PASd, and the light-emitting functional layer EL forms a fracture under the action of the I-shaped transition structure PAS. That is, the light-emitting functional layer EL forms a fracture at the edge of the second conductive layer PASc, to expose at least a part of the third conductive layer PASd and/or a side of the metal layer PASb. The second electrode COM not only covers the light-emitting functional layer EL, but also covers the part of the third conductive layer PASd that is not covered by the light-emitting functional layer EL and/or a side of the metal layer PASb. In this way, it may be achieved that the second electrode COM covers at least a part of the transition structure PAS.

For the above two embodiments, it may be that a partial edge of the second conductive layer PASc extends beyond the edge of the metal layer PASb, or it may be that the entire edge of the second conductive layer PASc extends beyond the edge of the metal layer PASb, and that is, an edge of the orthographic projection of the metal layer PASb on the substrate BP is located within the orthographic projection of the second conductive layer PASc on the substrate BP. When the edge of the orthographic projection of the metal layer PASb on the substrate BP is located within the orthographic projection of the second conductive layer PASc on the substrate BP, the probability of the fracture, occurring at the edge of the second conductive layer PASc, of the light-emitting functional layer EL may be increased, and it may be ensured that the first conductive layer PASa or the third conductive layer PASd are not completely covered by the light-emitting functional layer EL.

For the transition structure PAS including the first conductive layer PASa, the metal layer PASb, and the second conductive layer PASc, when the transition structure PAS is manufactured, a patterned first conductive layer PASa is first manufactured to facilitate the detection of the previously manufactured film layer structure. After the detection is completed, the entire metal layer PASb and the second conductive layer PASc are first manufactured, and the I-shaped transition structure PAS is obtained through etching. Since the metal layer PASb is in direct contact with the planarization layer PLA (the organic material layer) when the entire metal layer PASb is manufactured, the metal layer PASb is prone to bulging, which means that the manufactured transition structure PAS is prone to bulging.

For the transition structure PAS including the first conductive layer PASa, the third conductive layer PASd, the metal layer PASb, and the second conductive layer PASc, when the transition structure PAS is manufactured, after the patterned first conductive layer PASa is obtained, the third conductive layer PASd, the metal layer PASb, and the second conductive layer PASc may be simultaneously manufactured, and then the third conductive layer PASd, the metal layer PASb, and the second conductive layer PASc may be etched to obtain the I-shaped transition structure PAS. Since the entire third conductive layer PASd is manufactured first, and the third conductive layer PASd is the inorganic material layer, the contact between the metal layer PASb and the planarization layer PLA (the organic material layer) is avoided, so as to avoid the bulging of the metal layer PASb, and that is, to avoid the bulging of the transition structure PAS.

In the embodiments of the present disclosure, as shown in FIGS. 3 and 4, the source-drain metal layer SD includes a plurality of power lines VDDs in one-to-one correspondence with the plurality of groups of pixel circuits PDCAs. One power line VDD is connected to a corresponding group of pixel circuits PDCAs, and one power line VDD is located on a side of the corresponding group of pixel circuits PDCAs away from the auxiliary electrode PA.

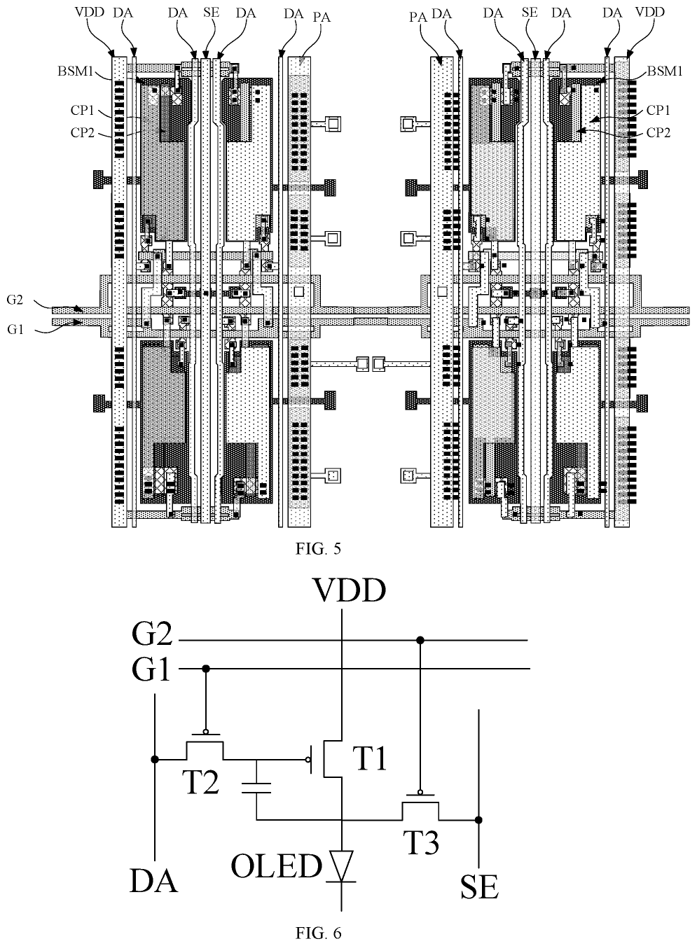

Thus, for the group of pixel circuits PDCAs, the power line VDD and the auxiliary electrode PA are arranged on both sides of the row direction, so as to increase a distance between the power line VDD and the auxiliary electrode PA, thereby avoiding mutual interference problems. For the plurality of groups of pixel circuits PDCAs, in order to avoid a close distance between the power line VDD and the auxiliary electrode PA, a wiring region between two adjacent groups of pixel circuits PDCAs includes either the power line VDD or the auxiliary electrode PA. For example, as shown in FIG. 5, the wiring region between two adjacent groups of pixel circuits PDCAs only includes the auxiliary electrode PA; or the wiring region between two adjacent groups of pixel circuits PDCAs includes both the power line VDD and the auxiliary electrode PA, and a distance between the power line VDD and the auxiliary electrode PA in the row direction is greater than a reference distance, so as to reduce the interference of the power line VDD corresponding to one group of pixel circuits PDCAs on the auxiliary electrode PA corresponding to the adjacent groups of pixel circuits PDCAs, and ensure the effectiveness of the arrangement of the auxiliary electrode PA (i.e., effectively reducing the voltage drop of the second electrode COM). For a case where the wiring region includes both the power line VDD and the auxiliary electrode PA, the distance between the power line VDD and the auxiliary electrode PA in the row direction may be determined according to specific experiments, which is not limited in the present disclosure.

As shown in FIG. 3 or FIG. 4, the auxiliary electrode PA is provided with an extension portion PA1 on a side of the auxiliary electrode PA away from the corresponding power line VDD, and there is an overlapping region between the orthographic projection of the transition structure PAS on the substrate BP and an orthographic projection of the extension portion PA1 on the substrate BP, and the second electrode COM covers at least a part of the transition structure PAS and is connected to the extension portion PA1. There may be one or more extension portions PA1. For example, as shown in FIG. 3 or FIG. 4, the auxiliary electrode PA is provided with four extension portions PA1, and the second electrode COM is connected to the four extension portions PA1 to ensure the stability of the connection between the second electrode COM and the auxiliary electrode PA.

In the embodiments of the present disclosure, the pixel circuit PDCA may be a circuit such as 3T1C, 4T1C, etc., as long as it may drive the light-emitting device to emit light. Next, the structure of the driving layer CL will be explained in detail using 3T1C as an example.

As shown in FIG. 6, the pixel circuit PDCA includes a first transistor T1, a second transistor T2, a third transistor T3, and a storage capacitor CP; a control electrode of the first transistor T1 is connected to a first electrode plate CP1 of the storage capacitor CP and a first electrode of the second transistor T2, the first electrode of the first transistor T1 is configured to load a power signal, a second electrode of the first transistor T1 is connected to a second electrode plate CP2 of the storage capacitor CP and a first electrode of the third transistor T3, and is connected to the first electrode An; a control electrode of the second transistor T2 is configured to load a first scanning signal, and a second electrode of the second transistor T2 is configured to load a data signal; a control electrode of the third transistor T3 is configured to load a second scanning signal, and a second electrode of the third transistor T3 is configured to load a sensing signal.

As shown in FIG. 1 or FIG. 2, the driving layer CL includes a shielding layer BSM, an insulation buffer layer BUF, a semiconductor layer ACT, a gate insulation layer GI, a gate metal layer Ga, an interlayer dielectric layer ILD, a source-drain metal layer SD, and a planarization layer PLN.

As shown in FIG. 1 or FIG. 2, and FIGS. 4, 7, 8, and 9, the shielding layer BSM is located on a side of the substrate BP and includes a shielding piece BSM1; the semiconductor layer ACT is located on a side of the shielding layer BSM away from the substrate BP, and includes an active portion of the first transistor T1, an active portion of the second transistor T2, and an active portion of the third transistor T3. The active portion includes a channel region and two connection portions located on both sides of the channel region; the gate metal layer Ga is located on a side of the semiconductor layer ACT away from the substrate BP, and includes a first scanning line G1, a second scanning line G2, and a second electrode plate CP2 of the storage capacitor CP, the first scanning line G1 loads the first scanning signal at the control electrode of the second transistor T2, and the second scanning line G2 loads the second scanning signal at the control electrode of the third transistor T3; the source-drain metal layer SD is located on a side of the gate metal layer Ga away from the substrate BP, and also includes a power line VDD, a data line DA, a sensing line SE, and a first electrode plate CP1 of the storage capacitor CP. The power line VDD loads the power signal at the first electrode of the first transistor T1, the data line DA loads the data signal at the second electrode of the second transistor T2, and the sensing line SE loads the sensing signal at the second electrode of the third transistor T3, the first electrode plate CP1 of the storage capacitor CP is directly opposite to the shielding piece BSM1 and connected to the shielding piece BSM1 through a via hole; the planarization layer PLN is located on a side of the source-drain metal layer SD away from the substrate BP, and at least covers the power line VDD, the data line DA, the sensing line SE, the first electrode CPI of the storage capacitor CP, and the auxiliary electrode PA.

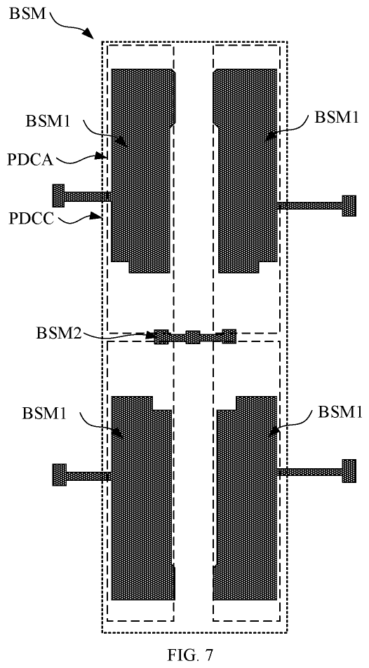

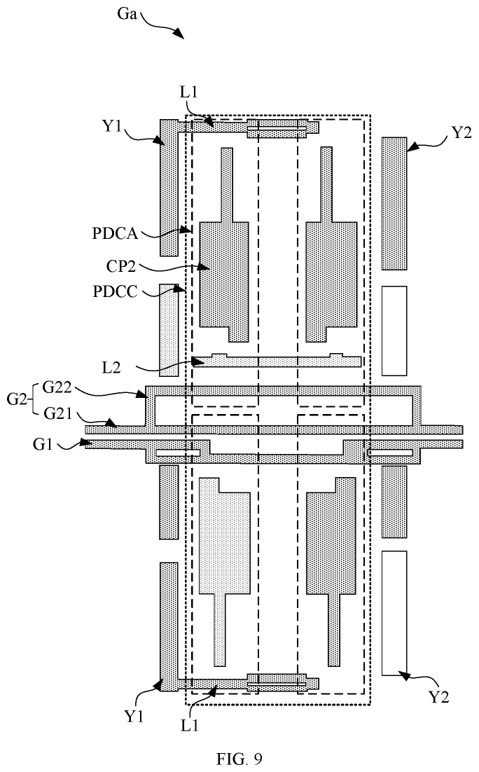

One group of pixel circuits PDCAs includes a plurality of circuit units PDCCs distributed in a column direction, and one unit circuit includes four pixel circuits PDCAs distributed in two rows and two columns. For one circuit unit PDCC, as shown in FIGS. 3 and 4, each of the power line VDD and the auxiliary electrode PA extends along the column direction and is distributed along the row direction, the power line VDD loads the power signal at the first electrodes of the first transistors T1 of the four pixel circuit PDCAs. As shown in FIGS. 3 and 7, four shielding pieces BSM1 are located between the power line VDD and the auxiliary electrode PA, and as shown in FIGS. 3, 8, and 9, orthographic projections of the first electrode plate CP1 and the second electrode plate CP2 of each storage capacitor CP on the substrate BP is located within an orthographic projection of the shielding piece BSM1 of the same pixel circuit PDCA on the substrate BP. As shown in FIGS. 3 and 9, the first scanning line G1 and the second scanning line G2 both extend along the row direction and are located between two shielding pieces BSM1 along the column direction, the first scanning line G1 loads the first scanning signal at the control electrodes of the second transistors T2 of the four pixel circuits PDCAs, and the second scanning line G2 loads the second scanning signal at the control electrodes of the third transistors T3 of the four pixel circuits PDCAs. As shown in FIGS. 3 and 4, the data line DA extends along the column direction, and the data line DA is provided on both sides of the two shielding pieces BSM1 along the row direction, four data lines DA are located between the power line VDD and the auxiliary electrode PA, and one data line DA loads the data signal at the second electrode of the second transistor T2 of one pixel circuit PDCA. As shown in FIGS. 3 and 4, the sensing line SE extends along the column direction and is located between the two shielding pieces BSM1 in the row direction, and the sensing line SE loads the sensing signal for the second electrodes of the third transistors T3 of the four pixel circuits PDCAs.

As shown in FIG. 7, the shielding layer BSM also includes a connection piece BSM2. As shown in FIG. 9, the gate metal layer Ga further includes a first horizontal segment L1 and a second horizontal segment L2, and a first vertical segment Y1 and a second vertical segment Y2. As shown in FIG. 4, the source-drain metal layer SD also includes a plurality of connection lines.

As shown in FIGS. 3, 4, 7, and 9, there is an overlapping region between a central portion of the connection piece BSM2 and the sensing line SE of the source-drain metal layer SD, which are connected through a via hole; the first horizontal segment L1 is connected to the first vertical segment Y1, and there is an overlapping region between the first vertical segment Y1 and the power line VDD of the source-drain metal layer SD, which are connected through a via hole; the second horizontal segment L2 is connected to the first scanning line G1 through a connection line LA; there is an overlapping region between the second vertical segment Y2 and the auxiliary electrode PA of the source-drain metal layer SD, which are connected through a via hole; the second scanning line G2 includes a scanning line body G21 and a scanning line branch G22 that extend along the row direction, the scanning line branch G22 is located on a side of the scanning line body G21 away from the first scanning line G1, and at least one end of the scanning line branch G22 is connected to the scanning line body G21.

In addition, there are at least two first horizontal segments L1 and at least two the first vertical segments Y1, and there may be one or more second vertical segments Y2.

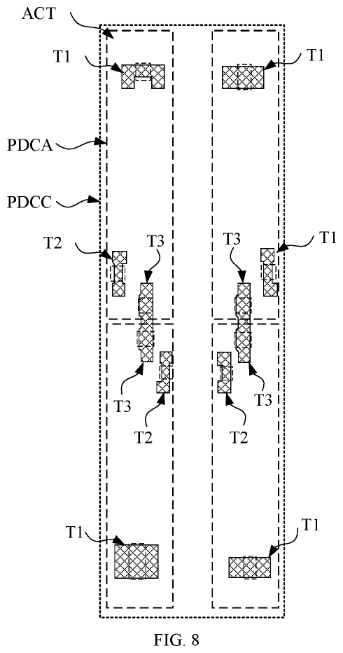

For one pixel circuit PDCA, as shown in FIGS. 3 and 8, there is an overlapping region between the orthographic projection of the channel region of the first transistor T1 on the substrate BP and the orthographic projection of the second electrode plate CP2 of the storage capacitor CP on the substrate BP. One connection portion of the first transistor T1 is connected to the first electrode plate CP1 of the storage capacitor CP through a via hole, and the other connection portion of the first transistor T1 is connected to the first horizontal segment L1 through a connection line LB; there is an overlapping region between the orthographic projection of a channel region of the second transistor T2 on the substrate BP and the orthographic projection of the second horizontal segment L2 on the substrate BP, one connection portion of the second transistor T2 is connected to the data line DA through a connection line LC, and the other connection portion of the second transistor T2 is connected to the second electrode plate CP2 of the storage capacitor CP through a connection line LD; there is an overlapping region between the orthographic projection of a channel region of the third transistor T3 on the substrate BP and an orthographic projection of the scanning line body G21 or the scanning line branch G22 on the substrate BP, one connection portion of the third transistor T3 is connected to the first electrode plate CP1 of the storage capacitor CP through a connection line LE, and the other connection portion of the third transistor T3 is connected to an end portion of the connection piece BSM2 through a connection line LF.

For one circuit unit PDCC, as shown in FIGS. 3 and 8, there are two pixel circuits PDCAs in the column direction, the active portions of the third transistors T3 of these two pixel circuits PDCAs are an integral structure, and that is, the two third transistors T3 share one connection portion, and the shared connection portion is configured to be connected to the end portion of the connection piece BSM2. For the two pixel circuits PDCAs in the row direction, the connection portions of the first transistors T1 of these two pixel circuits PDCAs are connected to the same first horizontal segment L1.

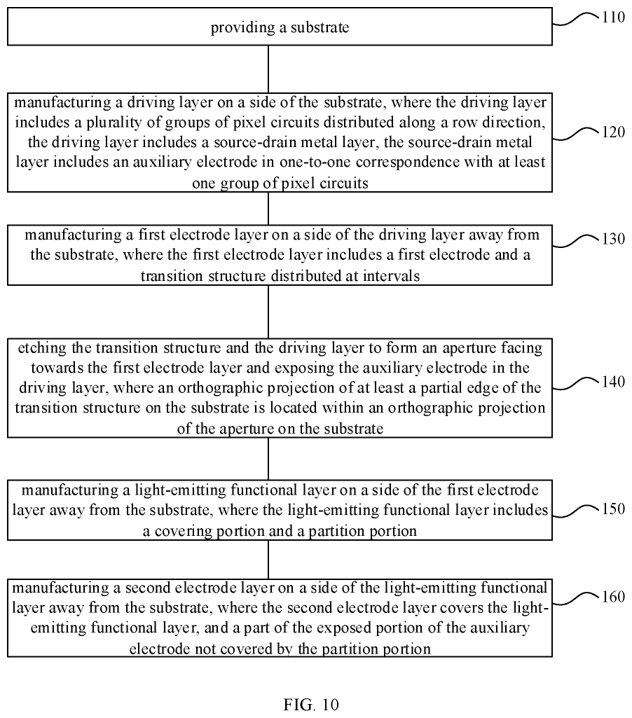

In the embodiments of the present disclosure, a method for manufacturing a display panel is also provided. The method is configured to manufacture the display panel as described in any one of above embodiments. As shown in FIG. 10, the method includes steps S110 to S160 as follows.

step S110: providing a substrate;

step S120: manufacturing a driving layer on a side of the substrate, where the driving layer includes a plurality of groups of pixel circuits distributed along a row direction, the driving layer includes a source-drain metal layer, the source-drain metal layer includes an auxiliary electrode in one-to-one correspondence with at least one group of pixel circuits, and the auxiliary electrode is located on a side of a group of pixel circuits corresponding to the auxiliary electrode;

step S130: manufacturing a first electrode layer on a side of the driving layer away from the substrate, where the first electrode layer includes a first electrode and a transition structure distributed at intervals, the first electrode is connected to the pixel circuit, and an orthographic projection of the transition structure on the substrate and an orthographic projection of the auxiliary electrode on the substrate have an overlapping region;

step S140: etching the transition structure and the driving layer to form an aperture facing towards the first electrode layer and exposing the auxiliary electrode in the driving layer, where an orthographic projection of at least a partial edge of the transition structure on the substrate is located within an orthographic projection of the aperture on the substrate;

step S150: manufacturing a light-emitting functional layer on a side of the first electrode layer away from the substrate, where the light-emitting functional layer includes a covering portion and a partition portion, the covering portion covers the first electrode and the transition structure, the partition portion is located within the aperture, and the covering portion and the partition portion form a fracture on at least a partial edge of the transition structure, and at least a partial edge of an orthographic projection of the exposed portion of the auxiliary electrode on the substrate extends beyond an orthographic projection of the partition portion on the substrate;

step S160: manufacturing a second electrode layer on a side of the light-emitting functional layer away from the substrate, where the second electrode layer covers the light-emitting functional layer, and a part of the exposed portion of the auxiliary electrode not covered by the partition portion.

Taking the transition structure including a first conductive layer, a metal layer, and a second conductive layer as an example, the process of etching the transition structure and the driving layer mentioned above specifically includes: forming entire layers of a first conductive layer, a metal layer, and a second conductive layer on a side of the driving layer away from the substrate in sequence; etching the first conductive layer, the metal layer, and the second conductive layer such that at least a partial edge of the second conductive layer extends beyond an edge of the metal layer, and the edge of the metal layer is at least flush with an edge of the first conductive layer; etching the driving layer such that the driving layer is defined with an aperture facing towards the first electrode layer, and an edge of the first conductive layer is flush with an aperture wall of the aperture, so as to ensure that the orthographic projection of at least partial edge of the transition structure on the substrate is located within the orthographic projection of the aperture on the substrate.

In the embodiments of the present disclosure, the second electrode covers a part of the exposed portion of the auxiliary electrode to achieve the connection between the second electrode and the auxiliary electrode, thereby effectively reducing the voltage drop of the second electrode and improving the potential uniformity of the second electrodes of the plurality of light-emitting devices, so as to ensure the uniformity of brightness when displaying the screen on the display panel. In addition, for the auxiliary electrode arranged in the source-drain metal layer, the auxiliary electrode may be arranged to extend in the column direction, to effectively increase an area of the orthographic projection of the auxiliary electrode on the substrate, thereby further reducing the voltage drop of the second electrode. Furthermore, for the transition structure, it is only necessary to ensure that the orthographic projection of at least a partial edge of the transition structure on the substrate is located within the orthographic projection of the aperture on the substrate, thereby avoiding a case where a thickness of the transition structure is relatively large and reducing a possibility of bulging during the manufacturing of the transition structure PAS; when the first electrodes of the plurality of light-emitting devices are obtained by etching, the transition structures may be obtained by etching simultaneously without manufacturing the transition structure separately, so as to simplify the manufacturing process.

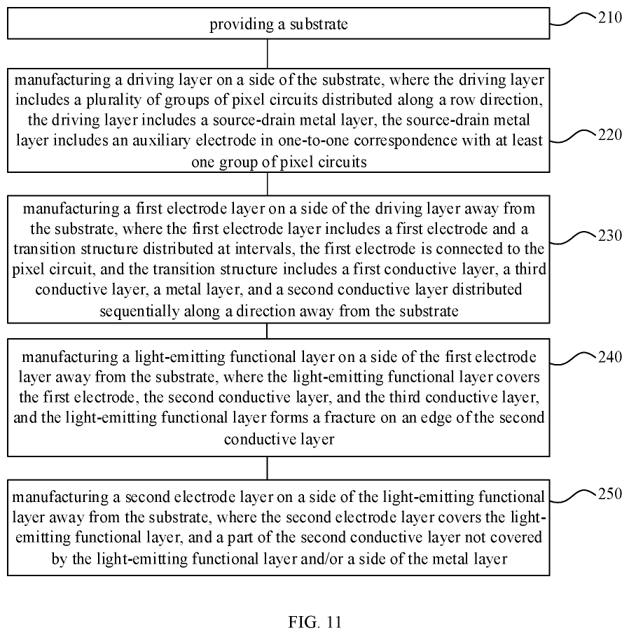

In the embodiments of the present disclosure, another method for manufacturing a display panel is also provided, which is used for manufacturing the display panel in another embodiment of the aforementioned embodiment. As shown in FIG. 11, the method includes steps S210 to S260 as follows.

step S210: providing a substrate;

step S220: manufacturing a driving layer on a side of the substrate, where the driving layer includes a plurality of groups of pixel circuits distributed along a row direction, the driving layer includes a source-drain metal layer, the source-drain metal layer includes an auxiliary electrode in one-to-one correspondence with at least one group of pixel circuits, and the auxiliary electrode is located on a side of a corresponding group of pixel circuits;

step S230: manufacturing a first electrode layer on a side of the driving layer away from the substrate, where the first electrode layer includes a first electrode and a transition structure distributed at intervals, the first electrode is connected to the pixel circuit, and the transition structure includes a first conductive layer, a third conductive layer, a metal layer, and a second conductive layer distributed sequentially along a direction away from the substrate, a material of the third conductive layer is an inorganic material, an orthographic projection of the metal layer on the substrate is located within an orthographic projection of the third conductive layer on the substrate, and at least a partial edge of the second conductive layer extends beyond an edge of the metal layer;

step S240: manufacturing a light-emitting functional layer on a side of the first electrode layer away from the substrate, where the light-emitting functional layer covers the first electrode, the second conductive layer, and the third conductive layer, and the light-emitting functional layer forms a fracture on an edge of the second conductive layer to expose at least a part of the third conductive layer and/or a side of the metal layer;

step S250: manufacturing a second electrode layer on a side of the light-emitting functional layer away from the substrate, where the second electrode layer covers the light-emitting functional layer, and a part of the third conductive layer not covered by the light-emitting functional layer and/or a side of the metal layer.

Taking the transition structure including a first conductive layer, a third conductive layer, a metal layer, and a second conductive layer as an example, the transition structure is arranged on a side of the driving layer away from the substrate, which specifically includes, forming a patterned first conductive layer on the driving layer, where the first conductive layer is connected to the auxiliary electrode through a via hole; sequentially forming entire layers of a third conductive layer, a metal layer, and a second conductive layer on a side of the first conductive layer away from the substrate; etching the third conductive layer, the metal layer, and the second conductive layer to form an I-shaped transition structure (the orthographic projection of the metal layer on the substrate is located within the orthographic projection of the third conductive layer on the substrate, and at least a partial edge of the second conductive layer extends beyond an edge of the metal layer).

In the embodiments of the present disclosure, the transition structure is connected to the auxiliary electrode through the via hole, and the second electrode covers a part of the transition structure to achieve the connection between the second electrode and the auxiliary electrode, thereby effectively reducing the voltage drop of the second electrode and improving the potential uniformity of the second electrodes of the plurality of light-emitting devices, so as to ensure the uniformity of brightness when displaying the screen on the display panel. In addition, for the auxiliary electrode arranged in the source-drain metal layer, the auxiliary electrode may be arranged to extend in the column direction, to effectively increase an area of the orthographic projection of the auxiliary electrode on the substrate, thereby further reducing the voltage drop of the second electrode. Furthermore, for the transition structure, the metal layer may be isolated from contacting the planarization layer (the organic material layer) through the third conductive layer, so as to avoid the bulging of the transition structure and improve the yield of the display panel.

It should be noted that although the various steps of the manufacturing method for the display panel in the present disclosure are described in a specific order in FIGS. 10 and 11, this does not require or imply that these steps must be performed in the specific order, or that all steps must be performed to achieve the desired results. Additionally or alternatively, certain steps may be omitted, multiple steps may be combined into one step for execution, and/or one step may be decomposed into multiple steps for execution.

The present disclosure also provides a display apparatus, which includes the display panel as described in the above embodiments. In this way, the use of the display panel described in the above method may effectively improve the uniformity of the display screen brightness of the display apparatus, thereby improving the display effect.

Other embodiments of the disclosure will be readily apparent to those skilled in the art from consideration of the specification and practice of the invention disclosed herein. This application is intended to cover any variations, uses, or adaptations of the disclosure that follow the general principles of the disclosure and include common knowledge or customary technical means in the technical field that are not disclosed in the disclosure. It is intended that the specification and examples be considered as exemplary only, with a true scope and spirit of the disclosure being indicated by the following claims.

1. A display panel, comprising:
a substrate;
a driving layer, located on a side of the substrate and comprising a plurality of groups of pixel circuits distributed along a row direction, wherein the driving layer comprises a source-drain metal layer, the source-drain metal layer comprises an auxiliary electrode in one-to-one correspondence with at least one group of pixel circuits, and the auxiliary electrode is located on a side of a group of pixel circuits corresponding to the auxiliary electrode; and
a light-emitting layer, located on a side of the driving layer away from the substrate, wherein the light-emitting layer comprises a light-emitting device and a transition structure distributed at intervals, an orthographic projection of the transition structure on the substrate and an orthographic projection of the auxiliary electrode on the substrate have an overlapping region, the light-emitting device comprises a first electrode, a light-emitting functional layer, and a second electrode sequentially distributed along a direction away from the substrate, the first electrode of the light-emitting device is connected to the pixel circuit, the light-emitting functional layer covers the first electrode and the transition structure, and forms a fracture on at least a partial edge of the transition structure, the second electrode covers the light-emitting functional layer and an exposed part of the transition structure at the fracture of the light-emitting functional layer, and the second electrode is connected to the auxiliary electrode.

2. The display panel according to claim 1, wherein the driving layer is defined with an aperture facing towards the light-emitting layer, and an orthographic projection of at least a partial edge of the transition structure on the substrate is located within an orthographic projection of the aperture on the substrate;
the auxiliary electrode comprises an exposed portion at the aperture, the light-emitting functional layer comprises a covering portion and a partition portion, wherein the covering portion and the partition portion form a fracture on at least a partial edge of the transition structure, the covering portion covers the first electrode and the transition structure, the partition portion is located within the aperture, and at least a partial edge of an orthographic projection of the exposed portion of the auxiliary electrode on the substrate extends beyond an orthographic projection of the partition portion on the substrate;
the second electrode covers a side of the transition structure, and a part of the exposed portion not covered by the partition portion, and a part of the second electrode covering the light-emitting functional layer and a part of the second electrode covering the exposed portion are continuous.

3. The display panel according to claim 2, wherein the transition structure is defined with an opening, and an orthographic projection of at least a partial opening edge of the transition structure on the substrate is located within the orthographic projection of the aperture on the substrate.

4. The display panel according to claim 3, wherein the opening of the transition structure coincides with a centerline of the aperture of the driving layer, and an opening size of the opening is less than an aperture size of the aperture.

5. The display panel according to claim 2, wherein a length of an edge of the transition structure extending into a corresponding region of the aperture is greater than or equal to 0.8 microns and less than or equal to 1.2 microns.

6. The display panel according to claim 2, wherein the transition structure comprises a first conductive layer, a metal layer, and a second conductive layer distributed sequentially along the direction away from the substrate;
an orthographic projection of at least a partial edge of at least one structural layer in the first conductive layer, the metal layer, and the second conductive layer on the substrate is located within the orthographic projection of the aperture on the substrate, and there is no overlapping region between an orthographic projection of remaining structural layers on the substrate and the orthographic projection of the aperture on the substrate.

7. The display panel according to claim 6, wherein each of the first conductive layer, the metal layer, and the second conductive layer is defined with an opening;
an opening edge of the first conductive layer and an opening edge of the metal layer are flush with an aperture wall of the aperture, and an orthographic projection of at least a partial opening edge of the second conductive layer on the substrate is located within the orthographic projection of the aperture on the substrate.

8. The display panel according to claim 1, wherein the transition structure is connected to the auxiliary electrode through a via hole.

9. The display panel according to claim 8, wherein the transition structure comprises a first conductive layer, a third conductive layer, a metal layer, and a second conductive layer distributed sequentially along the direction away from the substrate;
the first conductive layer is connected to the auxiliary electrode through a via hole, and a material of the third conductive layer is an inorganic material, an orthographic projection of the metal layer on the substrate is located within an orthographic projection of the third conductive layer on the substrate, and at least a partial edge of the second conductive layer extends beyond an edge of the metal layer;
the light-emitting functional layer covers the first electrode, the second conductive layer, and the third conductive layer, and the light-emitting functional layer forms a fracture on an edge of the second conductive layer to expose at least one of the following: at least a part of the third conductive layer or a side of the metal layer, and the second electrode layer further covers at least one of the following: a part of the third conductive layer not covered by the light-emitting functional layer or the side of the metal layer.

10. The display panel according to claim 9, wherein an edge of the orthographic projection of the metal layer on the substrate is located within an orthographic projection of the second conductive layer on the substrate.

11. The display panel according to claim 1, wherein the source-drain metal layer comprises a plurality of power lines in one-to-one correspondence with the plurality of groups of pixel circuits, the power line is connected to a group of pixel circuits corresponding to the power line, and the power line located on a side of the group of pixel circuits corresponding to the power line away from the auxiliary electrode.

12. The display panel according to claim 11, wherein the auxiliary electrode is provided with an extension portion on a side of the auxiliary electrode away from the power line corresponding to the auxiliary electrode, and there is an overlapping region between the orthographic projection of the transition structure on the substrate and an orthographic projection of the extension portion on the substrate, and the second electrode covers the transition structure and is connected to the extension portion.

13. The display panel according to claim 1, wherein the pixel circuit comprises a first transistor, a second transistor, a third transistor, and a storage capacitor;
a control electrode of the first transistor is connected to a first electrode plate of the storage capacitor and a first electrode of the second transistor, the first electrode of the first transistor is configured to load a power signal, and a second electrode of the first transistor is connected to a second electrode plate of the storage capacitor and a first electrode of the third transistor, and is connected to the first electrode;
a control electrode of the second transistor is configured to load a first scanning signal, and a second electrode of the second transistor is configured to load a data signal; and
a control electrode of the third transistor is configured to load a second scanning signal, and a second electrode of the third transistor is configured to load a sensing signal.

14. The display panel according to claim 13, wherein the driving layer comprises:
a shielding layer, located on a side of the substrate and comprising a shielding piece;
a semiconductor layer, located on a side of the shielding layer away from the substrate, and comprising an active portion of the first transistor, an active portion of the second transistor, and an active portion of the third transistor, wherein the active portion comprises a channel region and two connection portions located on both sides of the channel region;
a gate metal layer, located on a side of the semiconductor layer away from the substrate, and comprising a first scanning line, a second scanning line, and a second electrode plate of the storage capacitor, wherein the first scanning line loads the first scanning signal at the control electrode of the second transistor, and the second scanning line loads the second scanning signal at the control electrode of the third transistor;
a source-drain metal layer, located on a side of the gate metal layer away from the substrate, and comprising a power line, a data line, a sensing line, and a first electrode plate of the storage capacitor, wherein the power line loads the power signal at the first electrode of the first transistor, the data line loads the data signal at the second electrode of the second transistor, the sensing line loads the sensing signal at the second electrode of the third transistor, and the first electrode plate of the storage capacitor is directly opposite to the shielding piece and connected to the shielding piece through a via hole; and
a planarization layer, located on a side of the source-drain metal layer away from the substrate, and at least covers the power line, the data line, the sensing line, the first electrode plate of the storage capacitor, and the auxiliary electrode.

15. The display panel according to claim 14, wherein one group of pixel circuits comprises a plurality of circuit units distributed in a column direction, the unit circuit comprises four pixel circuits distributed in two rows and two columns, wherein for the circuit unit:
each the power line and the auxiliary electrode extends along the column direction and is distributed along the row direction, the power line loads the power signal at the first electrodes of the first transistors of the four pixel circuits;
four shielding pieces are located between the power line and the auxiliary electrode, and orthographic projections of the first and second electrode plates of each storage capacitor on the substrate is located within an orthographic projection of the shielding piece of the same pixel circuit on the substrate;
each of the first scanning line and the second scanning line extends in the row direction and is located between two shielding pieces along the column direction, the first scanning line loads the first scanning signal at the control electrodes of the second transistors of the four pixel circuits, and the second scanning line loads the second scanning signal at the control electrodes of the third transistors of the four pixel circuits;
the data line extends along the column direction, and the data line is provided on both sides of the two shielding pieces along the row direction, and four data lines are located between the power line and the auxiliary electrode, and one data line loads the data signal at the second electrode of the second transistor of one pixel circuit; and
the sensing line extends along the column direction and is located between the two shielding pieces in the row direction, and the sensing line loads the sensing signal for the second electrodes of the third transistors of the four pixel circuits.

16. A method for manufacturing a display panel, comprising providing a substrate;
manufacturing a driving layer on a side of the substrate, wherein the driving layer comprises a plurality of groups of pixel circuits distributed along a row direction, the driving layer comprises a source-drain metal layer, the source-drain metal layer comprises an auxiliary electrode in one-to-one correspondence with at least one group of pixel circuits, and the auxiliary electrode is located on a side of a group of pixel circuits corresponding to the auxiliary electrode;
manufacturing a first electrode layer on a side of the driving layer away from the substrate, wherein the first electrode layer comprises a first electrode and a transition structure distributed at intervals, the first electrode is connected to the pixel circuit, and an orthographic projection of the transition structure on the substrate and an orthographic projection of the auxiliary electrode on the substrate have an overlapping region;
etching the transition structure and the driving layer to form an aperture facing towards the first electrode layer and exposing the auxiliary electrode in the driving layer, wherein an orthographic projection of at least a partial edge of the transition structure on the substrate is located within an orthographic projection of the aperture on the substrate;
manufacturing a light-emitting functional layer on a side of the first electrode layer away from the substrate, wherein the light-emitting functional layer comprises a covering portion and a partition portion, the covering portion covers the first electrode and the transition structure, the partition portion is located within the aperture, and the covering portion and the partition portion form a fracture on at least a partial edge of the transition structure, and at least a partial edge of an orthographic projection of the exposed portion of the auxiliary electrode on the substrate extends beyond an orthographic projection of the partition portion on the substrate;
manufacturing a second electrode layer on a side of the light-emitting functional layer away from the substrate, wherein the second electrode layer covers the light-emitting functional layer, and a part of the exposed portion of the auxiliary electrode not covered by the partition portion.

17. A method for manufacturing a display panel, comprising
providing a substrate;
manufacturing a driving layer on a side of the substrate, wherein the driving layer comprises a plurality of groups of pixel circuits distributed along a row direction, the driving layer comprises a source-drain metal layer, the source-drain metal layer comprises an auxiliary electrode in one-to-one correspondence with at least one group of pixel circuits, and the auxiliary electrode is located on a side of a group of pixel circuits corresponding to the auxiliary electrode;
manufacturing a first electrode layer on a side of the driving layer away from the substrate, wherein the first electrode layer comprises a first electrode and a transition structure distributed at intervals, the first electrode is connected to the pixel circuit, and the transition structure comprises a first conductive layer, a third conductive layer, a metal layer, and a second conductive layer distributed sequentially along a direction away from the substrate, a material of the third conductive layer is an inorganic material, an orthographic projection of the metal layer on the substrate is located within an orthographic projection of the third conductive layer on the substrate, and at least a partial edge of the second conductive layer extends beyond an edge of the metal layer;
manufacturing a light-emitting functional layer on a side of the first electrode layer away from the substrate, wherein the light-emitting functional layer covers the first electrode, the second conductive layer, and the third conductive layer, and the light-emitting functional layer forms a fracture on an edge of the second conductive layer to expose at least one of the following: at least a part of the third conductive layer or a side of the metal layer;
manufacturing a second electrode layer on a side of the light-emitting functional layer away from the substrate, wherein the second electrode layer covers at least one of the following: the light-emitting functional layer, and a part of the third conductive layer not covered by the light-emitting functional layer and/or a side of the metal layer.

18. A display apparatus, comprising the display panel according to claim 1.

19. The display apparatus according to claim 18, wherein the driving layer is defined with an aperture facing towards the light-emitting layer, and an orthographic projection of at least a partial edge of the transition structure on the substrate is located within an orthographic projection of the aperture on the substrate;
the auxiliary electrode comprises an exposed portion at the aperture, the light-emitting functional layer comprises a covering portion and a partition portion, wherein the covering portion and the partition portion form a fracture on at least a partial edge of the transition structure, the covering portion covers the first electrode and the transition structure, the partition portion is located within the aperture, and at least a partial edge of an orthographic projection of the exposed portion of the auxiliary electrode on the substrate extends beyond an orthographic projection of the partition portion on the substrate;
the second electrode covers a side of the transition structure, and a part of the exposed portion not covered by the partition portion, and a part of the second electrode covering the light-emitting functional layer and a part of the second electrode covering the exposed portion are continuous.

20. The display apparatus according to claim 19, wherein the transition structure is defined with an opening, and an orthographic projection of at least a partial opening edge of the transition structure on the substrate is located within the orthographic projection of the aperture on the substrate.
